(19) United States
(12) Patent Application Publication
(10) Pub. No.: US 2012/0120547 A1
(43) Pub. Date: May 17, 2012

(54) CERAMIC ELECTRONIC COMPONENT AND METHOD OF MANUFACTURING THE SAME

(75) Inventors: Chi Hyoun RO, Yongin (KR); Yoon Sun Lee, Suwon (KR); Myung Jun Park, Cheongju (KR)

(73) Assignee: SAMSUNG ELECTRO-MECHANICS CO., LTD.

(21) Appl. No.: 13/024,888

(22) Filed: Feb. 10, 2011

(30) Foreign Application Priority Data
Nov. 16, 2010 (KR) 10-2010-0114137

(51) Int. Cl. H01G 4/12; H05K 3/00

(52) U.S. Cl. 361/321.3; 29/842

(57) ABSTRACT

There is provided a ceramic electronic component and a method of manufacturing the same. The method of manufacturing the ceramic electronic component includes: forming a fluorine coating layer on a ceramic sintered body, the fluorine coating layer having wettability of an external electrode paste lower than that of the external electrode paste on the ceramic sintered body and including carbon; and forming an external electrode by applying the external electrode paste on a surface of the ceramic sintered body.

### CROSS-REFERENCE TO RELATED APPLICATIONS

This application claims the priority of Korean Patent Application No. 10-2010-0114137 filed on Nov. 16, 2010, in the Korean Intellectual Property Office, the disclosure of which is incorporated herein by reference.

### BACKGROUND OF THE INVENTION

1. Field of the Invention

The present invention relates to a method of manufacturing a ceramic electronic component, and more particularly, to a method of manufacturing a ceramic electronic component capable of improving the reliability of chips by preventing the mooning phenomenon of external electrodes of the ceramic electronic component.

2. Description of the Related Art

As electronic products increasingly shrink in size, various components of the electronic products are accordingly being miniaturized and manufactured in a chip type.

As a representative example, a small capacitor made of a ceramic material has been already developed in a small chip type and is currently being used. The capacitor includes a first external electrode and a second external electrode having a predetermined width, which are formed at both ends of a chip-type body made of a ceramic material having a dielectric constant.

A process of manufacturing the above-mentioned chip-type capacitor is as follows. First, a chip-type capacitor body is made of ceramic. A copper paste is applied to both ends of the chip-type body to form the first external electrode and the second external electrode.

Generally, in order to facilitate a manufacturing process, a method of applying a copper paste by dipping one end of a chip body thereinto is used. Then, the copper paste is subjected to heat treatment so that it rapidly forms an electrode.

Similar to the above-mentioned method, the copper paste is applied to the other end of the chip body through dipping and is subjected to the heat treatment. In this manner, a first external electrode and a second external electrode are formed at both ends of the chip body.

In the manufacturing of the chip-type capacitor according to the related art, a phenomenon in which the middle portions of copper paste of the first external electrode and the second external electrode are extendedly spread on a chip body in half moon shapes occurs during a process of forming the first external electrode and the second external electrode through the application and drying of the copper paste.

That is, while an interface between the external electrodes should be formed in a straight line, it is, however, substantially formed to have a semi-circular shape due to the above-mentioned reason. The phenomenon of forming the external electrodes adopting a semi-circular shape is referred to as a mooning phenomenon and the longest distance of a semi-circle deviated from the straight line is referred to as a mooning size.

In this case, the widths of the first external electrode and the second external electrode play an important role in mounting chip-type components on a printed circuit board (PCB). In particular, they play an important role in surface mount technology (SMT).

As the mooning size is increased, the bandwidth of the external electrode is dispersed and serves as a factor in generating dispersion at the time of the mounting of the chip. In addition, standard defects and pick up defects of the chip and the like, are caused.

Therefore, many attempts to minimize mooning size have been conducted.

### SUMMARY OF THE INVENTION

An aspect of the present invention provides a method of manufacturing a ceramic electronic component capable of improving the reliability of chips by preventing a mooning phenomenon in the forming of external electrodes of the ceramic electronic component and preventing dispersion at the time of mounting chips.

According to an aspect of the present invention, there is provided a ceramic electronic component including: a ceramic sintered body in which a plurality of ceramic layers and a plurality of inner electrodes are alternately stacked; a fluorine coating layer formed on the ceramic sintered body, having wettability of an external electrode paste lower than that of the external electrode paste on the ceramic sintered body, and including carbon; and an external electrode formed on the fluorine coating layer.

The external electrode may have a mooning size, defined by a difference between a maximum bandwidth of the external electrode and a minimum bandwidth of the external electrode, corresponding to 20% or less of the maximum bandwidth of the external electrode.

The external electrode may have a mooning size, defined by a difference between a maximum bandwidth of the external electrode and a minimum bandwidth of the external electrode, corresponding to 10% or less of the maximum bandwidth of the external electrode.

The fluorine coating layer may be formed of a fluorine coating solution including carbon.

The fluorine coating solution may include a fluoro copolymer.

The fluorine coating layer may include 1 part or less by weight of the fluoro copolymer per 100 parts by weight of the fluorine coating solution.

The fluorine coating layer may further include 30 to 39 parts by weight of hydrofluoro carbon per 100 parts by weight of the fluorine coating solution.

The fluorine coating layer may further include 60 to 69 parts by weight of perfluoro compound per 100 parts by weight of the fluorine coating solution.

According to another aspect of the present invention, there is provided a method of manufacturing a ceramic electronic component, the method including: forming a fluorine coating layer on a ceramic sintered body, the fluorine coating layer having wettability of an external electrode paste lower than that of the external electrode paste on the ceramic sintered body and including carbon; and forming an external electrode by applying the external electrode paste on a surface of the ceramic sintered body.

The forming of the fluorine coating layer may include forming a mesh packaging body by packaging the ceramic sintered body with a mesh; dipping the mesh packaging body into a fluorine coating solution; and drying the ceramic sintered body coated with the fluorine coating solution.

The fluorine coating solution may include a fluoro copolymer.

The fluorine coating layer may include 1 part or less by weight of the fluoro copolymer per 100 parts by weight of the fluorine coating solution.

The fluorine coating layer may further include 30 to 39 parts by weight of hydrofluoro carbon per 100 parts by weight of the fluorine coating solution.

The fluorine coating layer may further include 60 to 69 parts by weight of perfluoro compound per 100 parts by weight of the fluorine coating solution.

The external electrode may have a mooning size, defined by a difference between a maximum bandwidth of the external electrode and a minimum bandwidth of the external electrode, corresponding to 20% or less of the maximum bandwidth of the external electrode.

The external electrode may have a mooning size, defined by a difference between a maximum bandwidth of the external electrode and a minimum bandwidth of the external electrode, corresponding to 10% or less of the maximum bandwidth of the external electrode.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a plan view of a ceramic electronic component according to an exemplary embodiment of the present invention;

FIG. 2 is a cross-sectional view showing a contact angle formed between a ceramic sintered body and a paste according to an exemplary embodiment of the present invention;

FIG. 3 is a front view of a ceramic electronic component according to an exemplary embodiment of the present invention;

FIGS. 4A through 4C are views showing a method of coating fluorine on a ceramic sintered body according to an exemplary embodiment of the present invention;

FIG. 5 is an image showing a fluorine content on a surface of a ceramic sintered body according to an exemplary embodiment of the present invention;

FIG. 6 is a graph showing a mooning size of a ceramic electronic component according to an exemplary embodiment of the present invention; and

FIG. 7 is a graph showing a bonding strength of the ceramic electronic component according to an exemplary embodiment of the present invention.

### DETAILED DESCRIPTION OF THE PREFERRED EMBODIMENT

Exemplary embodiments of the present invention will now be described in detail with reference to the accompanying drawings. However, it should be noted that the spirit of the present invention is not limited to the embodiments set forth herein, and those skilled in the art and understanding the present invention could easily accomplish retrogressive inventions or other embodiments included in the spirit of the present invention by the addition, modification, and removal of components within the same spirit, and those are to be construed as being included in the spirit of the present invention.

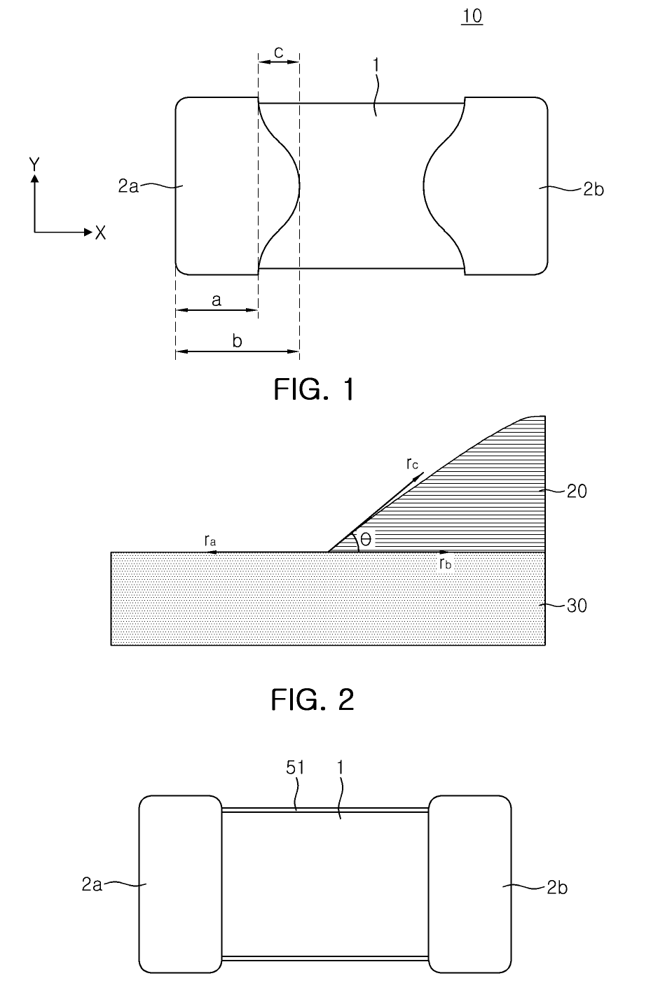

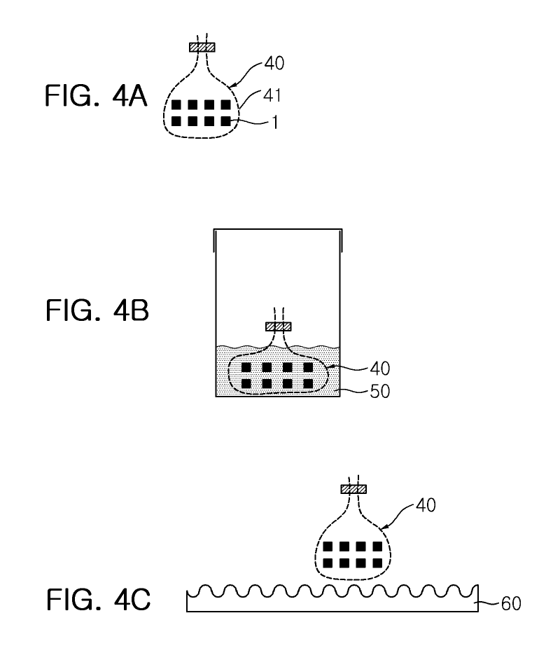

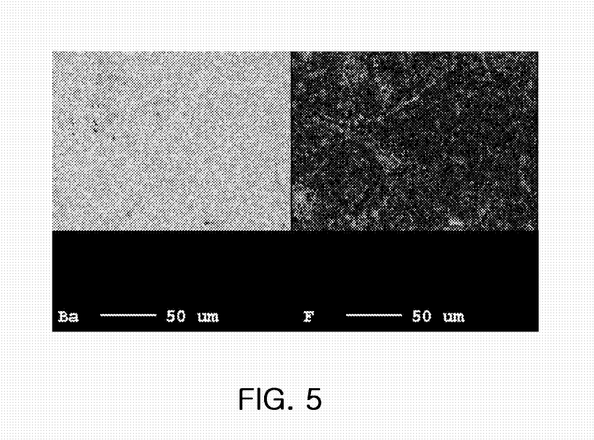

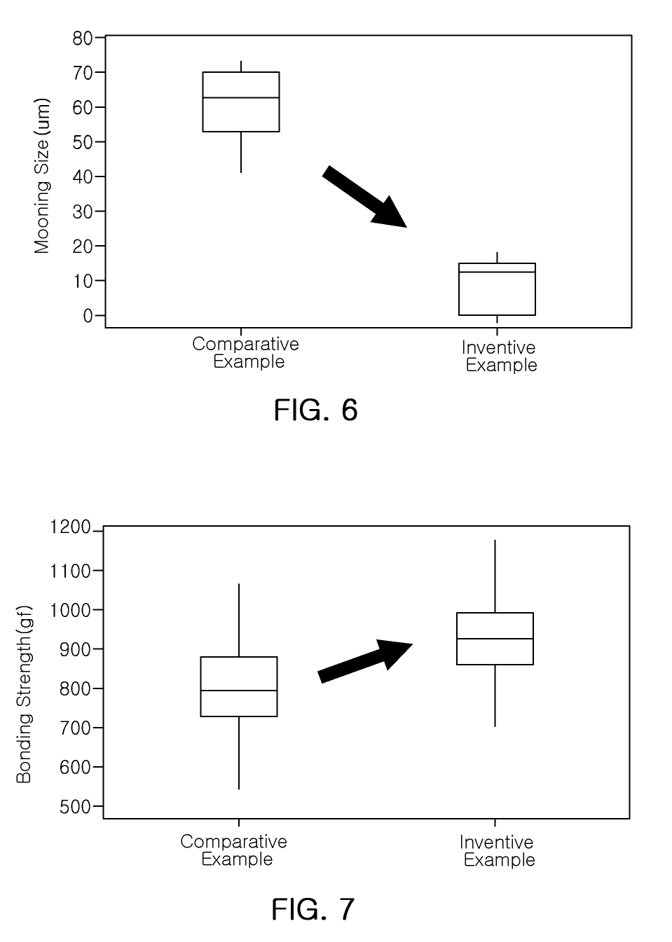

FIG. 1 is a plan view of a ceramic electronic component according to an exemplary embodiment of the present invention; FIG. 2 is a cross-sectional view showing a contact angle formed between a ceramic sintered body and a paste according to an exemplary embodiment of the present invention; FIG. 3 is a front view of a ceramic electronic component according to an exemplary embodiment of the present invention; FIGS. 4A through 4C show a method of coating fluorine on a ceramic sintered body according to an exemplary embodiment of the present invention; FIG. 5 is an image showing a fluorine content on a surface of a ceramic sintered body according to an exemplary embodiment of the present invention; FIG. 6 is a graph showing a mooning size of a ceramic electronic component according to an exemplary embodiment of the present invention; and FIG. 7 is a graph showing a bonding strength of a ceramic electronic component according to an exemplary embodiment of the present invention.

FIG. 1 is a plan view of a ceramic electronic component according to an exemplary embodiment of the present invention.

Referring to FIG. 1, a ceramic electronic component 10 includes a ceramic sintered body 1 formed by alternately stacking a plurality of ceramic layers and inner electrodes, and a first external electrode 2a and a second external electrode 2b respectively formed at both ends of the ceramic sintered body 1 and connecting the inner electrodes to an external device.

The ceramic sintered body 1 is formed by stacking a plurality of ceramic layers, and at least one or more inner electrodes implementing the electrical characteristics of a chip are formed between dielectric layers. At least two of the inner electrodes include leads (not shown) electrically connected to the external electrodes, and thus may be electrically connected to the external electrodes.

The external electrodes serve to electrically connect the inner electrodes to external devices and are made of an excellent conductive material. Although not limited thereto, the external electrodes may be made of at least one selected from the group consisting of Cu, Ag, Ni, and Pd.

Referring to FIG. 1, an x-directional width of the external electrodes each formed at both ends of the ceramic sintered body is referred to as a bandwidth. When a minimum bandwidth of the bandwidth is referred to as ‘a’ and a maximum bandwidth of the bandwidth is referred to as ‘b’, a difference between the maximum bandwidth b and the minimum bandwidth ‘a’ is referred to as a mooning size ‘c’.

Although it is preferable that the bandwidth of the external electrode be constant, a phenomenon, in which a middle portion of an external electrode paste may be extendedly spread on a chip body 1 in a half moon shape may occur during a process of applying and drying the paste. This is referred to as a “mooning phenomenon” and the difference between the maximum bandwidth and the minimum bandwidth shown by the mooning phenomenon is referred to as the mooning size c.

As the mooning size c is large, the bonding strength is weakened at the time of mounting the chip, and chip defects such as standard defects, pick up defects, tombstone defects in which one side of the chip rises, or the like, are caused.

FIG. 2 is a cross-sectional view showing a contact angle formed between a ceramic sintered body and an external electrode paste according to an exemplary embodiment of the present invention and is a partially enlarged view of a surface 30 of the ceramic sintered body 1 of FIG. 1.

Referring to FIG. 2, an external electrode paste 20 formed on the surface 30 of the ceramic sintered body may be inclined by θ with respect to the surface 30 of the ceramic sintered body. The θ forms a contact angle of the external electrode paste 20 with respect to the ceramic sintered body.

The external electrode paste 20 on the surface 30 of the ceramic sintered body is applied with various forces. The external electrode paste 20 is applied with attractive force due to the difference between the surface 30 of the ceramic sintered body and the surface energy of air, as well as with its own surface tension.

The external electrode paste 20 forms the contact angle θ by a resultant force of various forces.

A wetting force γa of the external electrode paste 20 with respect to the surface 30 of the ceramic sintered body satisfies the following equation for the contact angle θ, together with various forces γb and γc applied to the external electrode paste 20:

$${γ}_{a} = {γ}_{b} + {γ}_{c} cos θ , \\ cos θ = \frac{{γ}_{a} - {γ}_{b}}{{γ}_{c}} \qquad Equation 1$$

The larger the wetting force γa is, the smaller the contact angle θ becomes, while the smaller the wetting force γa is, the larger the contact angle θ becomes.

In other words, the external electrode paste 20 has a strong wetting force with respect to the surface 30 of the ceramic sintered body, such that the contact angle is small as the spreadability to the surface 30 of the ceramic sintered body increases, while the external electrode paste 20 has a weak wetting force with respect to the surface 30 of the ceramic sintered body, such that the contact angle is large as the spreadability to the surface 30 of the ceramic sintered body decreases.

In other words, as the wetting force with respect to the surface contacting the external electrode paste 20 is weak, the spreadability is poor, such that the mooning phenomenon, in which the middle portion of the external electrode paste 20 is exceedingly spread, is reduced.

FIG. 3 is a front view of a ceramic electronic component according to an exemplary embodiment of the present invention.

Referring to FIG. 3, the ceramic electronic component according to this embodiment of the present invention includes the ceramic sintered body 1, a fluorine coating layer 51 including carbon formed on the ceramic sintered body 1, and the first external electrode 2a and the second external electrode 2b formed on the fluorine coating layer 51.

The ceramic electronic component of the present invention may be a multilayer ceramic capacitor as an example.

According to the exemplary embodiment of the present invention, referring to FIG. 3, the fluorine coating layer 51 including carbon may be formed on the ceramic sintered body 1. The flurorine coating layer 51 is formed of a fluorine coating solution including carbon, and the coating can be made by dipping the ceramic sintered body 1 into a liquid fluorine coating solution.

As a result, the flurorine coating layer 51 maybe formed by a simple method, and when the flurorine coating layer 51 is formed, the wettability of the external electrode paste may be weakened.

That is, since the external electrode paste has a weaker wettability with respect to the surface having the flurorine coating layer 51 formed thereon than the wettability with respect to the surface of the ceramic sintered body, the spreadability of the external electrode paste is weakened when the fluorine coating layer 51 is formed.

As a result, the mooning phenomenon occurring due to the excessive spread of the external electrode paste can be prevented.

According to the exemplary embodiment of the present invention, the fluorine coating layer may be applied with the fluorine coating solution including carbon, and the fluorine coating solution may include a liquid fluoro copolymer.

The fluorine coating layer may include 1 part or less by weight of the fluoro copolymer per 100 parts by weight of the flurorine coating solution, and may further include 30 to 39 parts by weight of hydrofluoro carbon per 100 parts by weight of the fluorine coating solution. Further, 60 to 69 parts by weight of perfluoro compounds per 100 parts by weight of the fluorine coating solution may be included.

Since the flurorine coating solution of the present invention includes carbon and is manufactured in a liquid phase, the coating may be made by simply dipping the ceramic sintered body 1 in the coating solution.

In the case of the ceramic electronic component formed with the fluorine coating layer according to the exemplary embodiment of the present invention, the spreadability may be minimized, thereby reducing the mooning size.

When the first external electrode 2a and the second external electrode 2b are formed on the multilayer ceramic sintered body 1 having the fluorine coating layer 51 formed thereon according to the exemplary embodiment of the present invention, the mooning size of the external electrode may be 20% or less of the maximum bandwidth of the external electrode, preferably, 10% or less thereof.

As an example, in a case of manufacturing a multilayer ceramic chip having a 0603 size, that is, 0.6 mm in length and 0.3 mm in width and thickness, the fluorine coating layer 51 may be formed on the ceramic sintered body in order to form an external electrode having a bandwidth of 150 μm.

In the case in which the external electrode is formed on the ceramic sintered body 1 having the fluorine coating layer 51 formed thereon, the difference between the maximum bandwidth and the minimum bandwidth, i.e., the mooning size may be 60 μm or less, preferably, 30 μm or less.

When the fluorine coating layer 51 is formed, the mooning size of the external electrode may be reduced to 20% or less of the maximum bandwidth, preferably, 10% or less thereof.

Therefore, the bonding strength of the mounted terminals is reinforced by minimizing the mooning effect of the ceramic electronic component and the standard defects, the pick up defects, the tombstone defects, and the like can be prevented.

A method of coating fluorine on a ceramic sintered body according to an exemplary embodiment of the present invention will be described with reference to FIGS. 4A through 4C.

Referring to FIGS. 4A through 4C, in order to manufacture external electrodes in a ceramic electronic component, the ceramic sintered body 1 is first prepared.

The ceramic sintered body 1 is formed by stacking a plurality of dielectric layers such as ceramic and a plurality of inner electrodes that are formed between the plurality of dielectric layers in order to manufacture an electronic component having desired electrical characteristics.

The inner electrodes may include at least two leads, and the leads are connected to the external electrodes to perform the electrical function of the chip.

FIG. 4A shows packaging the ceramic sintered body 1 with a mesh.

According to the exemplary embodiment of the present invention, in order to coat the surface of the ceramic sintered body 1 in which the dielectric layers and the inner electrodes are alternately stacked, a mesh packaging body 40 is manufactured by putting the plurality of ceramic sintered bodies 1 in the mesh 41 in order to prevent the contents of the ceramic sintered bodies 1 from being leaked and sealing the mesh 41 while providing a spare space therein to the extent that the ceramic sintered bodies 1 rotate.

FIG. 4B shows the dipping of the mesh packaging body 40 into the fluorine coating solution. The sealed mesh packaging body 40 is dipped into the fluorine coating solution 50 filled in a chamber to be widely spread. Then, the chamber is sealed.

The flurorine coating solution may include a fluoro copolymer. The fluoro copolymer may be mixed to have 1 part or less by weight per 100 parts by weight of the fluorine coating solution.

The fluorine coating solution 50 including the fluoro copolymer is coated on the surface 30 the ceramic sintered body to thereby lower the wettability of the surface 30 of the ceramic sintered body. Therefore, the interface energy between the surface 30 of the ceramic sintered body and the external electrode paste 20 is formed to be small, thereby minimizing the mooning effect.

The fluorine coating layer may include 30 to 39 parts by weight of hydrofluoro carbon per 100 parts by weight of the fluorine coating solution. Also, the fluorine coating layer may further include 60 to 69 parts by weight of perfluoro compounds per 100 parts by weight of the fluorine coating solution.

The mesh packaging body is put into the fluorine coating solution and the chamber is sealed and shaken up and down, thereby coating the ceramic sintered bodies 1 in the mesh with the fluorine coating solution.

FIG. 4C shows drying the ceramic sintered bodies coated with the fluorine coating solution.

After the fluorine coating is performed, the mesh packaging body 40, in which the ceramic sintered bodies 1 are contained, is taken out from the mesh packaging body 40. The fluorine coating solution is discharged from the mesh by taking out the mesh packaging body 40 and then, the fluorine coating solution remaining in the mesh packaging body 40 is absorbed into an absorbing part 60 absorbing humidity, such as a cloth, through a natural dry process.

Thereafter, the ceramic sintered bodies 1 having the fluorine coating layers formed thereon are dipped into the external electrode paste 20 contained in the chamber, thereby forming the external electrodes.

Since the fluorine coating layer 51 is formed on the surface of the ceramic sintered body 1, the wettability of the external electrode paste on the surface of the ceramic sintered body having the fluorine coating layer 51 formed thereon is weaker than the wettability of the external electrode paste on the surface of the ceramic sintered body.

Consequently, when the external electrode paste is applied to the surface on which the fluorine coating layer is formed, the surface having the fluorine coating layer formed thereon is subject to the weak wettability of the external electrode paste, such that the spreadability is weak. Therefore, the excessive spreading of the external electrode paste is prevented and the mooning effect can be prevented accordingly.

Hereinafter, the present invention will be described in more detail with reference to inventive and comparative examples. However, the scope of the present invention is not limited to the following examples.

### INVENTIVE EXAMPLE 1

A fluorine coating solution was coated on a ceramic sintered body according to an exemplary embodiment of the present invention.

First, the ceramic sintered body to be surface-treated was put in a mesh having a size sufficient so as not to leak the ceramic sintered body. The mesh is firmly bound so as not to leak the ceramic sintered body while providing a spare space in which the ceramic sintered body can flow. The spare space, in which the ceramic sintered body could flow, was prepared to the extent that the ceramic sintered body rotates once.

A mesh packaging body including the ceramic sintered body was widely spread on the bottom surface of a round plastic container. Then, a surface-treatment material, that is, a fluorine coating solution was filled in the plastic container to a predetermined level.

Per 100 parts by weight of the fluorine coating solution, 1 part or less by weight of fluoro copolymer including carbon, 30 to 39 parts by weight of hydrofluoro carbon, and 60 to 69 parts by weight of perfluoro compound were included.

The plastic container, in which the fluorine coating solution was contained, was sealed and then, the plastic container was shaken by at least 30 cm up and down for a total of 20 times or more, such that the fluorine coating solution was coated on the ceramic sintered body.

Then, the mesh packaging body was taken out from the plastic container, the liquid dropping was performed for about 1 minute so that the fluorine coating solution was sufficiently dropped from the top portion of the plastic container. Then, the mesh packaging body was put on a cloth, and the fluorine coating solution was completely removed therefrom by 10 cm or more for a total of 20 times or more.

After the fluorine coating solution was removed, the ceramic sintered body was taken out from the mesh packaging body and was then subjected to the application of an external electrode paste.

FIG. 5 is an image showing the surface of the ceramic sintered body after the fluorine coating solution was coated thereon. When the fluorine coating solution was coated by the above-mentioned method, it could be confirmed that fluoro F components were detected on the surface of the ceramic sintered body.

### INVENTIVE EXAMPLE 2

According to an exemplary embodiment of the present invention, an external electrode having a bandwidth of about 150 μm was formed on a chip of 0603 size, that is, 0.6 mm in length and 0.3 mm in width and thickness.

A comparative example in which an external electrode is formed without coating a fluorine coating solution including carbon on a ceramic sintered body and an inventive example in which an external electrode is formed by coating a fluorine coating solution including carbon were compared.

In this case, when the fluorine coating solution including carbon was not treated, the mooning size was about 60 μm; however, when the fluorine coating solution including carbon was treated, the mooning size was reduced to be 15 μm.

FIG. 6 is a graph showing the mooning size of a ceramic electronic component when an external electrode having a bandwidth of 150 μm is formed by treating a fluorine coating saluting according to an exemplary embodiment of the present invention.

That is, when the treatment of the fluorine coating solution including carbon was not performed on a 0606 size chip, it could be confirmed that the mooning size was large; however, when the treatment of the fluorine coating solution was performed, the mooning size was reduced by about 75%.

That is, when the external electrode having the bandwidth of 150 μm was formed, the external electrode having the mooning size of 30 μm or less could be formed, preferably, the external electrode having the mooning size of 15 μm or less could be formed.

In other words, in the forming of the external electrode of the ceramic electronic component according to the exemplary embodiment of the present invention, the external electrode could be formed to have the mooning size corresponding to 20% or less of the maximum bandwidth thereof, preferably, 10% or less of the maximum bandwidth.

FIG. 7 is a graph showing a bonding strength of a ceramic electronic component when an external electrode was formed by treating a fluorine coating solution according to an exemplary embodiment of the present invention.

It could be confirmed that when the fluorine coating solution treatment was not performed on the 0603 size chip, the bonding strength was about 500 gf; however, after the fluorine coating solution treatment was performed, the bonding strength was about 700 gf, which was raised by 200 gf. That is, it could be confirmed that the bonding strength of the chip subjected to the fluorine coating solution treatment was improved by about 40%.

It could be confirmed that when the fluorine coating solution was formed on the ceramic electronic component according to the exemplary embodiment of the present invention, the mooning size was reduced by 25% or less as compared with the related art, and the reduced mooning size led to an increase of bonding strength by 40% or more at the time of mounting the chip.

Therefore, according to the exemplary embodiment of the present invention, the mooning phenomenon is prevented in forming the external electrodes of the ceramic electronic components, whereby the dispersion of the chips can be prevented at the time of mounting the chips. That is, the external electrode, in which the mooning phenomenon is suppressed, can be formed.

Further, a method of manufacturing ceramic electronic components capable of preventing standard defects by reducing the shape deviations of the external electrode, pick up defects caused when the chip is mounted, and shape defects such as tombstone defects can be provided.

As set forth above, according to exemplary embodiments of the present invention, a mooning phenomenon is avoided in forming external electrodes of the ceramic electronic components, whereby the dispersion of chips can be prevented at the time of mounting the chips. Further, a method of manufacturing ceramic electronic components capable of preventing standard defects, pick up defects, and the like, by reducing the shape deviations of the external electrodes.

While the present invention has been shown and described in connection with the exemplary embodiments, it will be apparent to those skilled in the art that modifications and variations can be made without departing from the spirit and scope of the invention as defined by the appended claims.

What is claimed is:

1. A ceramic electronic component comprising:
a ceramic sintered body in which a plurality of ceramic layers and a plurality of inner electrodes are alternately stacked;
a fluorine coating layer formed on the ceramic sintered body, having wettability of an external electrode paste lower than that of the external electrode paste on the ceramic sintered body, and including carbon; and
an external electrode formed on the fluorine coating layer.

2. The ceramic electronic component of claim 1, wherein the external electrode has a mooning size, defined by a difference between a maximum bandwidth of the external electrode and a minimum bandwidth of the external electrode, corresponding to 20% or less of the maximum bandwidth of the external electrode.

3. The ceramic electronic component of claim 1, wherein the external electrode has a mooning size, defined by a difference between a maximum bandwidth of the external electrode and a minimum bandwidth of the external electrode, corresponding to 10% or less of the maximum bandwidth of the external electrode.

4. The ceramic electronic component of claim 1, wherein the fluorine coating layer is formed of a fluorine coating solution including carbon.

5. The ceramic electronic component of claim 4, wherein the fluorine coating solution includes a fluoro copolymer.

6. The ceramic electronic component of claim 5, wherein the fluorine coating layer includes 1 part or less by weight of the fluoro copolymer per 100 parts by weight of the fluorine coating solution.

7. The ceramic electronic component of claim 6, wherein the fluorine coating layer further includes 30 to 39 parts by weight of hydrofluoro carbon per 100 parts by weight of the fluorine coating solution.

8. The ceramic electronic component of claim 6, wherein the fluorine coating layer further includes 60 to 69 parts by weight of perfluoro compound per 100 parts by weight of the fluorine coating solution.

9. A method of manufacturing a ceramic electronic component, the method comprising:
forming a fluorine coating layer on a ceramic sintered body, the fluorine coating layer having wettability of an external electrode paste lower than that of the external electrode paste on the ceramic sintered body and including carbon; and
forming an external electrode by applying the external electrode paste on a surface of the ceramic sintered body.

10. The method of claim 9, wherein the forming of the fluorine coating layer comprises:
forming a mesh packaging body by packaging the ceramic sintered body with a mesh;
dipping the mesh packaging body into a fluorine coating solution; and
drying the ceramic sintered body coated with the fluorine coating solution.

11. The method of claim 10, wherein the fluorine coating solution includes a fluoro copolymer.

12. The method of claim 11, wherein the fluorine coating layer includes 1 part or less by weight of the fluoro copolymer per 100 parts by weight of the fluorine coating solution.

13. The method of claim 12, wherein the fluorine coating layer further includes 30 to 39 parts by weight of hydrofluoro carbon per 100 parts by weight of the fluorine coating solution.

14. The method of claim 12, wherein the fluorine coating layer further includes 60 to 69 parts by weight of perfluoro compound per 100 parts by weight of the fluorine coating solution.

15. The method of claim 9, wherein the external electrode has a mooning size, defined by a difference between a maximum bandwidth of the external electrode and a minimum bandwidth of the external electrode, corresponding to 20% or less of the maximum bandwidth of the external electrode.

16. The method of claim 9, wherein the external electrode has a mooning size, defined by a difference between a maximum bandwidth of the external electrode and a minimum bandwidth of the external electrode, corresponding to 10% or less of the maximum bandwidth of the external electrode.
